(19) United States
(12) Patent Application Publication
(10) Pub. No.: US 2026/0005137 A1
(43) Pub. Date: Jan. 1, 2026

(54) INTEGRATED DIE CIRCUIT

(71) Applicant: Cirrus Logic International Semiconductor Ltd., Edinburgh (GB)

(72) Inventors: Lee R. COLEMAN, Newbury (GB); Omid AMIRI, Edinburgh (GB); Rupesh KHARE, Newbury (GB)

(73) Assignee: Cirrus Logic International Semiconductor Ltd., Edinburgh (GB)

(21) Appl. No.: 18/754,623

(22) Filed: Jun. 26, 2024

(51) Int. Cl. H01L 23/528; H03K 17/00

(52) U.S. Cl. CPC H01L 23/528; H03K 17/002

(57) ABSTRACT

An integrated circuit (IC) die configured for packaging in a plurality of different IC packages, the IC die comprising: a first set of die contacts positioned in a first region of the integrated circuit die; a second set of die contacts positioned in a second region of the integrated circuit die; a package type contact; and routing circuitry configured to selectively route signals to or from either the first set of die contacts or the second set of die contacts based on a package type signal received at the package type contact.

### FIELD OF THE INVENTION

The present disclosure relates to an integrated circuit (IC) die configured to be packaged in a plurality of different IC packages.

### BACKGROUND

A packaged integrated circuit (IC) comprises a die of a semiconductor material such as silicon on which electronic circuitry is fabricated, encapsulated in a protective package which is typically of a plastics or ceramic material.

The die is provided with a plurality of die contacts (e.g. contact pads or bond pads), including power supply contacts to enable electrical power to be supplied to the die and input and output contacts to permit electrical signals to be input to and output from the die. The input and output contacts are typically positioned on one edge of the die.

The protective package includes a plurality of external connectors such as conductive pins, pads or balls. The external connectors of the package are electrically coupled, internally of the package, to the die contacts, e.g. by electrical conductors such as bond wires or the like, such that, in use of the packaged IC die, an electrical signal supplied to a particular external connector of the package is conducted to the die contact to which the particular electrical connector is coupled.

In use of the packaged IC die, the package is mounted on a suitable substrate such as a printed circuit board, with its external connectors coupled (e.g. by soldering) to power supply and signal lines (e.g. PCB tracks) of the substrate.

### SUMMARY

According to a first aspect, the invention provides an integrated circuit (IC) die configured for packaging in a plurality of different IC packages, the IC die comprising: a first set of die contacts positioned in a first region of the integrated circuit die; a second set of die contacts positioned in a second region of the integrated circuit die; a package type contact; and routing circuitry configured to selectively route signals to or from either the first set of die contacts or the second set of die contacts based on a package type signal received at the package type contact.

The first set of die contacts may be configured to be coupled to external contacts of an integrated circuit package of a first configuration. The second set of die contacts may be configured to be coupled to external contacts of an integrated circuit package of a second configuration.

The first set of die contacts may be disposed on a first side of the IC die. The second set of die contacts may be disposed on a second side of the IC die, wherein the second side is opposed to the first side.

The routing circuitry may comprise an input multiplexer configured to select the first set of die contacts or the second set of die contacts for receiving an input signal based on the package type signal.

The routing circuitry may comprise: a first input enable multiplexer configured to selectively enable output contacts of the first set of die contacts based on the package type signal; and a second input enable multiplexer configured to selectively enable output contacts of the first set of die contacts based on the package type signal.

The routing circuitry may further comprise: a first output enable multiplexer configured to selectively enable output contacts of the first set of die contacts based on the package type signal; and a second output enable multiplexer configured to selectively enable output contacts of the first set of die contacts based on the package type signal.

The routing circuitry may further comprise an output demultiplexer configured to select the first set of die contacts or the second set of die contacts for outputting an output signal based on the package type signal.

The routing circuitry may further comprise routing core circuitry configured to couple an output of the input multiplexer to an input of downstream circuitry of the IC die.

The routing core circuitry may be further configured to couple an output of the downstream circuitry to the first and second sets of die contacts.

The routing circuitry may further comprise routing core circuitry configured to: couple an output of the input multiplexer to an input of downstream circuitry of the IC die; and couple an output of the downstream circuitry to an input of the output demultiplexer.

The first and second sets of die contacts may be for receiving and/or outputting communications signals.

The communications signals may be communication signals according to the Inter-Integrated Circuit (I²C) protocol or the Serial Peripheral Interface (SPI) protocol.

According to a second aspect, the invention provides an integrated circuit comprising an IC die according to the first aspect.

According to a third aspect, the invention provides a host device comprising an integrated circuit according to the second aspect.

The host device may comprise a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

According to a fourth aspect, the invention provides an integrated circuit (IC) comprising an IC die, the IC die comprising: a first set of die contacts positioned in a first region of the integrated circuit die; a second set of die contacts positioned in a second region of the integrated circuit die; a package type contact; and routing circuitry configured to selectively route signals to or from either the first set of die contacts or the second set of die contacts based on a package type signal received at the package type contact, wherein the package type contact is coupled, internally of the IC die, to a package type signal source which supplies the package type signal.

The package type signal source may comprise a first or a second power supply input contact of the IC die.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a simplified schematic representation of an example IC die according to the present disclosure;

FIG. 2 is a schematic representation of a further example IC die according to the present disclosure;

FIG. 3 is a schematic representation of a further example IC die according to the present disclosure; and

FIG. 4 is a schematic representation of a packaged integrated circuit comprising an IC die according to the present disclosure.

### DETAILED DESCRIPTION

Some IC dies implement electronic circuitry that is designed or suitable for a plurality of different applications. Such IC dies may be packaged in different IC packages that are specific to particular applications.

For example, a single IC die may implement a converter (e.g. an analog to digital converter or a digital to analog converter) that can be configured as either a four-channel converter or a six-channel converter. For applications that require a four-channel converter, the IC die may be encapsulated in a first IC package having a first configuration of external connectors, whereas for applications that require a six-channel converter, the IC die may be packaged in a second IC package having a second configuration (different from the first configuration) of external connectors.

A challenge that can arise in the use of such multi-application IC dies lies in making electrical connections between the die contacts of the IC die and the external connectors of each different package in which the IC die can be encapsulated. In particular, in some package configurations space and layout constraints can make routing of bond wires or other electrical connectors from the die contacts of the IC die to the external connectors of the package difficult.

The present disclosure relates to an IC die configured for packaging in a plurality of differently-configured IC packages that facilitates routing of bond wires or other electrical conductors between die contacts of the IC die and external connectors of the IC package.

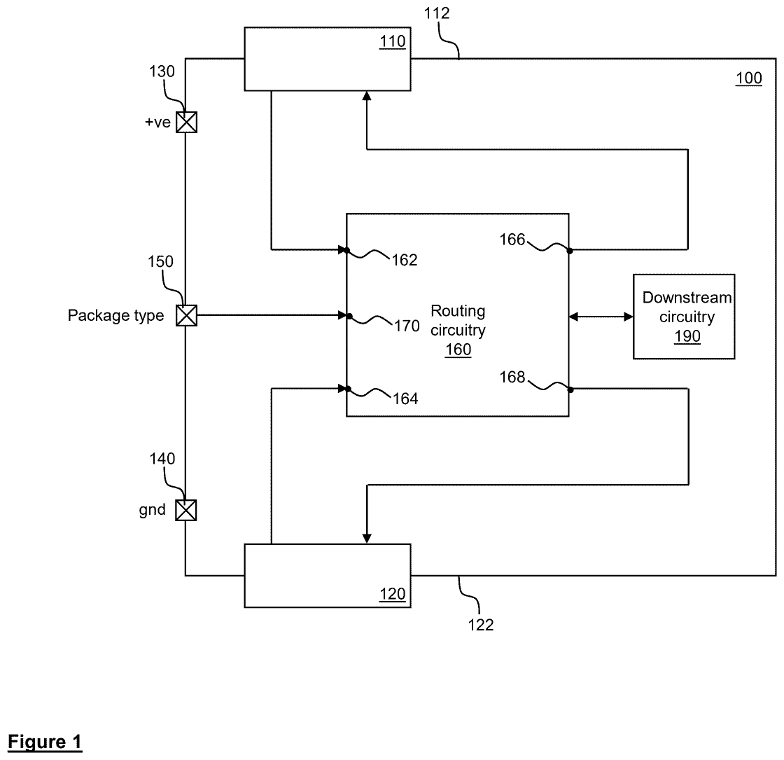

FIG. 1 is a simplified schematic representation of an IC die according to the present disclosure.

The IC die, shown generally at 100 in FIG. 1, comprises a first set of die contacts 110 disposed in a first region of the IC die 100. In the illustrated example the first set of die contacts 110 is disposed on a first side 112 of the IC die 100, but it will be appreciated by those of ordinary skill in the art that the first set of die contacts 110 may be positioned in any region of the IC die 100 that facilitates coupling of the first set of die contacts 110 to external contacts (e.g. pins, pads or balls) of an IC package of a first type or configuration in which the IC die 100 may be encapsulated. The first set of die contacts 110 may include one or more input contacts for receiving input signals to the die 100 and one or more output contacts for outputting signals from the die 100.

The IC die 100 further comprises a second set of die contacts 120, disposed in a second region of the IC die 100. In the illustrated example the second set of die contacts 120 is disposed on a second side 122 of the IC die 100, which is opposite the first side 112 of the die 100, but again, it will be appreciated by those of ordinary skill in the art that the second set of die contacts 120 may be positioned in any region (different than the first region) of the IC die 100 that facilitates coupling of the second set of die contacts 120 to external contacts (e.g. pins, pads or balls) of an IC package of a second type or configuration in which the IC die 100 may be encapsulated.

The die contacts of the first and second sets may each comprise contact pads or bond pads, for example.

The IC die 100 further includes a first and second power supply input contacts 130, 140 for receiving a positive power supply voltage and a reference power supply voltage (e.g. a ground or negative supply voltage) respectively, to power the IC die 100.

The IC die 100 further includes a package type contact 150, for receiving a package type signal indicative of the type or configuration of a package in which the IC die 100 is encapsulated.

The IC die 100 further includes signal routing circuitry 160, which in this example is implemented in digital circuitry, configured to route input signals received at either the first or second set of die contacts 110, 120 to downstream circuitry 190 of the IC die 100, based on the package type signal received at the package type contact 150, and to route output signals from the downstream circuitry 190 to either the first or second set of die contacts 110, 120, again based on the package type signal received at the package type input contact 150.

The signal routing circuitry 160 has a first input (or set of inputs) 162 coupled to the first set of die contacts 110, for receiving one or more input signals from the first set of die contacts 110, and a second input (or set of inputs) 164 coupled to the second set of die contacts 120, for receiving one or more input signals from the second set of die contacts 120.

The signal routing circuitry 160 also has a first output (or set of outputs) 166 coupled to the first set of die contacts 110, for outputting one or more output signals to the first set of contacts, and a second output (or set of outputs 168) coupled to the second set of die contacts 120, for outputting one or more output signals to the second set of die contacts 120.

The signal routing circuitry 160 further includes a package type input 170 coupled to the package type contact 150, for receiving the package type signal indicative of the type or configuration of the package in which the IC die 100 is encapsulated.

The signal routing circuitry 160 is configured to selectively route input signals from the first set of die contacts 110 or the second set of die contacts 120 to the downstream circuitry 190, based on the package type signal, and to selectively route output signals from the downstream circuitry to the first set of die contacts 110 or the second set of die contacts 120, based on the package type signal.

Thus, if the package type signal is indicative that the IC die 100 is encapsulated in a package of a first configuration, the signal routing circuitry 160 may be operative to route input signals received at the first set of die contacts 110 to the downstream circuitry 190, and may be operative to route output signals received from the downstream circuitry 190 to the first set of die contacts 110. On the other hand, if the package type signal is indicative that the IC die 100 is encapsulated in a package of a second configuration, the signal routing circuitry 160 may be operative to route input signals received at the second set of die contacts 120 to the downstream circuitry 190, and may be operative to route output signals received from the downstream circuitry 190 to the second set of die contacts 120.

The package type signal received at the package type contact 150 is defined during manufacture of the packaged IC containing the IC die 100. For example, if the package is of a first configuration, the first set of die contacts 110 may be coupled to external contacts (e.g. pins, pads, balls or the like) of the package and used for receiving input signals to the IC die 100 and for outputting output signals from the IC die 100. To indicate this, the package type contact 150 may be connected (e.g. bonded), internally of the IC die 100, to the second power supply input contact 140, so as to receive the reference power supply voltage. Thus, in use of the IC die 100, the signal routing circuitry 160 receives at its package type input 170 a signal indicative that the first set of die contacts 110 is to be used for receiving input signals and outputting output signals, and accordingly routes input signals from the first set of die contacts 110 and routes output signals to the first set of die contacts 110.

In contrast, if the package is of a second configuration, the second set of die contacts 120 may be coupled to the external contacts of the package and used for receiving input signals to the IC die 100 and for outputting output signals from the IC die 100. To indicate this, the package type contact 150 may be connected (e.g. bonded), internally of the IC die 100, to the first power supply input contact 130, so as to receive the positive power supply voltage. Thus, in use of the IC die 100, the signal routing circuitry 160 receives at its package type input 170 a signal indicative that the second set of die contacts 120 is to be used for receiving input signals and outputting output signals, and accordingly routes input signals from the second set of die contacts 120 and routes output signals to the second set of die contacts 120.

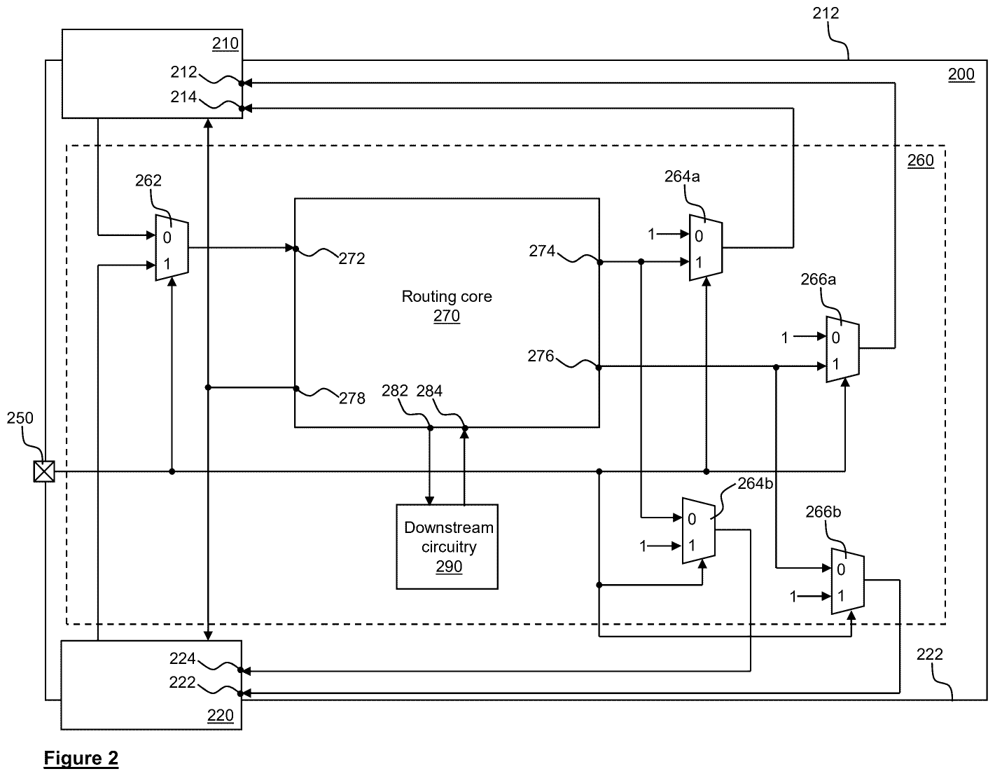

FIG. 2 is schematic representation of a further example IC die according to the present disclosure.

Like the IC die 100 of FIG. 1, the IC die of FIG. 200, shown generally at 200, comprises a first set of die contacts 210 and a second set of die contacts 220, which in the illustrated example are disposed, respectively, in respective first and second regions of the IC die 200. In the illustrated example the first and second sets of die contacts 210, 220 are positioned, respectively, on opposite first and second sides 212, 222 of the IC die 200, but it will be appreciated by those of ordinary skill in the art that the first set of die contacts 210 may be positioned in any region of the IC die 200 that facilitates coupling of the first set of die contacts 210 to external contacts (e.g. pins, pads or balls) of an IC package of a first type or configuration in which the IC die 200 may be encapsulated, and the second set of die contacts 220 may be positioned in any other region of the IC die 200 that facilitates coupling of the second set of die contacts 220 to external contacts (e.g. pins, pads or balls) of an IC package of a second type or configuration in which the IC die 200 may be encapsulated.

The first and second sets of die contacts 210, 220 may each include one or more input contacts for receiving input signals to the die 200 and one or more output contacts for outputting signals from the die 200. The IC die 200 further includes a first and second power supply input contacts, which are not shown in FIG. 2 for the sake of clarity) for receiving a positive power supply voltage and a reference power supply voltage (e.g. a ground or negative supply voltage) respectively, to power the IC die 200.

The IC die 200 further includes a package type contact 250, for receiving a package type signal indicative of the type or configuration of a package in which the IC die 200 is encapsulated.

The IC die 200 further includes signal routing circuitry 260 (shown in dashed outline in FIG. 2), which in this example is implemented in digital circuitry, configured to route input signals received at either the first or second set of die contacts 210, 220 to downstream circuitry 290 of the IC die 200, based on the package type signal received at the package type contact 250, and to route output signals from the downstream circuitry 290 to either the first or second set of die contacts 210, 220, again based on the package type signal received at the package type contact 250.

The signal routing circuitry 260 in this example comprises an input multiplexer 262, first and second input enable multiplexers 264a, 264b, first and second output enable multiplexers 266a, 266b and routing core circuitry 270.

The input multiplexer 262 has a first input (or set of inputs) coupled to the first set of die contacts 210, for receiving one or more input signals from the first set of die contacts 210, a second input (or set of inputs) coupled to the second set of contacts 220, for receiving one or more input signals from the second set of contacts 220, and a select input coupled to the package type contact 250, for receiving the package type signal. An output (or set of outputs) of the input multiplexer 262 is coupled to a die contact input (or set of die contact inputs) 272 of the routing core circuitry 270.

The first input enable multiplexer 264a has a first input that receives a fixed logic 1 signal (e.g. the first input may be coupled to a positive power supply input or rail of the die 200). A second input of the first input enable multiplexer 264a is coupled to an input enable output 274 of the routing core circuitry 270, which outputs a logic 0 signal. A select input of the first input enable multiplexer 264a is coupled to the package type contact 250, for receiving the package type signal. An output of the first input enable multiplexer 264a is coupled to an input enable contact of or associated with the first set of die contacts 210.

The second input enable multiplexer 264b has a first input coupled to the input enable output 274 of the routing core circuitry 270. A second input of the second input enable multiplexer 264b receives a fixed logic 1 signal. A select input of the second input enable multiplexer 264b is coupled to the package type contact 250, for receiving the package type signal. An output of the second input enable multiplexer 264b is coupled to an input enable contact of or associated with the second set of die contacts 220.

The first output enable multiplexer 266a has a first input that receives a fixed logic 1 signal. A second input of the first output enable multiplexer 266a is coupled to an output enable output 276 of the routing core circuitry 270, which outputs a logic 0 signal. A select input of the first output enable multiplexer 266a is coupled to the package type contact 250, for receiving the package type signal. An output of the first output enable multiplexer 266a is coupled to an output enable contact of or associated with the first set of die contacts 210.

The second output enable multiplexer 266b has a first input coupled to the output enable output 276 of the routing core circuitry 270. A second input of the second output enable multiplexer 266b receives a fixed logic 1 signal. A select input of the second output enable multiplexer 266b is coupled to the package type contact 250, for receiving the package type signal. An output of the second output enable multiplexer 266b is coupled to an output enable contact of or associated with the second set of die contacts 220.

The routing core circuitry 270 further includes a die contact output (or set of die contact outputs) 278 that is coupled to the first and second sets of die contacts 210, 220, for supplying output signals from downstream circuitry 290 to either the first set of die contacts 210 or the second set of die contacts 220, depending on the type or configuration of the package in which the IC die 200 is encapsulated. Similarly, the die contact input (or set of die contact inputs) 272 of the routing core circuitry 270 is for supplying input signals received at either the first set of die contacts 210 or the second set of die contacts 220, depending on the type or configuration of the package in which the die 200 is encapsulated, to the downstream circuitry 290.

To these ends, the die contact input (or set of die contact inputs) 272 of the routing core circuitry 270 is coupled, internally of the routing core circuitry 270, to a routing core output (or a set of routing core outputs) 282 to which an input (or set of inputs) of the downstream circuitry 290 is coupled. Similarly, the die contact output (or set of die contact outputs) 278 of the routing core circuitry 270 is coupled, internally of the routing core circuitry 270, to a routing core input (or a set of routing core inputs) 284 to which an output (or set of outputs) of the downstream circuitry 290 is coupled.

The signal routing circuitry 260 is configured to selectively route input signals from the first set of die contacts 210 or the second set of contacts 220 to the downstream circuitry 290, based on the package type signal, and to selectively route output signals from the downstream circuitry 290 to the first set of die contacts 210 or the second set of contacts 220, based on the package type signal, as will now be explained.

Thus, if the package type signal is indicative that the IC die 200 is encapsulated in a package of a first configuration, the signal routing circuitry 260 may be operative to route input signals received at the first set of die contacts 210 to the downstream circuitry 290, and may be operative to route output signals received from the downstream circuitry 290 to the first set of die contacts 210. On the other hand, if the package type signal is indicative that the IC die 200 is encapsulated in a package of a second configuration, the signal routing circuitry 260 may be operative to route input signals received at the second set of die contacts 220 to the downstream circuitry 290, and may be operative to route output signals received from the downstream circuitry 290 to the second set of die contacts 220.

The package type signal received at the package type contact 250 is defined during manufacture of the packaged IC containing the IC die 200. For example, if the package is of a first configuration, the first set of die contacts 210 may be coupled to external contacts (e.g. pins, pads, balls or the like) of the package and used for receiving input signals to the IC die 200 and for outputting output signals from the IC die 200. To indicate this, the package type contact 250 may be connected (e.g. bonded), internally of the IC die 200, to the second power supply input contact, so as to receive the reference power supply voltage. In this case, the select inputs of the input multiplexer 262, the first and second input enable multiplexers 264a, 264b and the first and second output enable multiplexers 266a, 266b each receive a logic 0 signal.

In response to receiving a logic 0 signal at its select input, the input multiplexer 262 couples its first input (or set of inputs) to its output (or set of outputs), such that the first set of die contacts 210 is coupled to the die contact input (or set of die contact inputs) 272 of the routing core circuitry 270, thus selecting the first set of die contacts 210. As noted above, the die contact input (or set of die contact inputs) 272 of the routing core circuitry 270 is internally coupled to the routing core output (or set of outputs) 282. Thus, the first set of die contacts 210 can be coupled to the routing core output (or set of outputs) 282 and thus to the input (or set of inputs) of the downstream circuitry 290.

In response to receiving a logic 0 at its select input, the first input enable multiplexer 264a couples its first input to its output, such that a logic 1 signal is output to the input enable contact of or associated with the first set of die contacts 210, to enable input contacts of the first set of die contacts 210, thus allowing input signals to be received via the first set of die contacts 210.

In response to receiving a logic 0 at its select input, the second input enable multiplexer 264b couples its first input to its output, such that a logic 0 signal is output to the input enable contact of or associated with the second set of die contacts 220, to disable input contacts of the second set of die contacts 220, thus preventing input signals from being received via the second set of die contacts 220.

In response to receiving a logic 0 at its select input, the first output enable multiplexer 266a couples its first input to its output, such that a logic 1 signal is output to the output enable contact of or associated with the first set of die contacts 210, to enable output contacts of the first set of die contacts 210, thus allowing output signals to be output via the first set of die contacts 210.

In response to receiving a logic 0 at its select input, the second output enable multiplexer 266b couples its first input to its output, such that a logic 0 signal is output to the output enable contact of or associated with the second set of die contacts 220, to disable output contacts of the second set of die contacts 220, thus preventing output signals from being output via the second set of die contacts 220.

As noted above, the routing core input (or set of inputs) 284 is internally coupled to the die contact output (or set of die contact outputs) 278 of the routing core circuitry 270, which is in turn coupled to both the first set 210 and the second set 220 of die contacts. Thus, by enabling the output contacts of the first set of die contacts 210, signals output by the downstream circuitry 290 can be routed to both the first set 210 and the second set 220 of die contacts, but will only be output by the enabled die contacts of the first set 210.

In contrast, if the package is of a second configuration, the second set of die contacts 220 may be coupled to the external contacts of the package and used for receiving input signals to the IC die 200 and for outputting output signals from the IC die 200. To indicate this, the package type contact 250 may be connected (e.g. bonded), internally of the IC die 200, to the first power supply input contact, so as to receive the positive power supply voltage. In this case, the select inputs of the input multiplexer 262, the first and second input enable multiplexers 264a, 264b and the first and second output enable multiplexers 266a, 266b each receive a logic 1 signal.

In response to receiving a logic 1 signal at its select input, the input multiplexer 262 couples its second input (or set of inputs) to its output (or set of outputs), such that the second set of die contacts 220 is coupled to the die contact input (or set of die contact inputs) 272 of the routing core circuitry 270, thus selecting the second set of die contacts 220. As noted above, the die contact input (or set of die contact inputs) 272 of the routing core circuitry 270 is internally coupled to the routing core output (or set of outputs) 282. Thus, the second set of die contacts 220 can be coupled to the routing core output (or set of outputs) 282 and thus to the input (or set of inputs) of the downstream circuitry 290.

In response to receiving a logic 1 at its select input, the first input enable multiplexer 264a couples its second input to its output, such that a logic 0 signal is output to the input enable contact of or associated with the first set of die contacts 210, to disable the input contacts of the first set of die contacts 210 thus preventing input signals from being received via the first set of die contacts 210.

In response to receiving a logic 1 at its select input, the second input enable multiplexer 264b couples its second input to its output, such that a logic 1 signal is output to the input enable contact of or associated with the second set of die contacts 220, to enable the input contacts of the second set of die contacts 220, thus allowing input signals to be received via the second set of die contacts 220.

In response to receiving a logic 1 at its select input, the first output enable multiplexer 266a couples its second input to its output, such that a logic 0 signal is output to the output enable contact of or associated with the first set of die contacts 210, to disable the output contacts of the first set of die contacts 210, thus preventing output signals from being output via the first set of die contacts 210.

In response to receiving a logic 1 at its select input, the second output enable multiplexer 266b couples its second input to its output, such that a logic 1 signal is output to the output enable contact of or associated with the second set of die contacts 220, to enable output contacts of the second set of die contacts 220, thus allowing output signals to be output via the second set of die contacts 220.

As noted above, the routing core input (or set of inputs) 284 is internally coupled to the die contact output (or set of die contact outputs) 278 of the routing core circuitry 270, which is in turn coupled to both the first set 210 and the second set 220 of die contacts. Thus, by enabling the output contacts of the second set of die contacts 220, signals output by the downstream circuitry 290 can be routed to both the first set 210 and the second set 220 of die contacts, but will only be output by the enabled die contacts of the second set 220.

Those of ordinary skill in the art will appreciate that the input multiplexer 262 could be omitted, and the first and second sets of IC contacts 210, 220 could instead be coupled to the die contact input (or set of die contact inputs) 272 of the routing core circuitry 270. In such an arrangement, enabling either the first set 210 or the second set 220 of die contacts via the signals output by the first and second input enable multiplexers 264a, 264b would be sufficient to enable selection of either the first set of die contacts 210 or the second set of die contacts 220 for receiving input signals.

Similarly, the first and second input enable multiplexers 264a, 264b and the input enable inputs of or associated with the first and second sets of die contacts 210, 220 could be omitted. In such an arrangement, the input multiplexer 262 enables selection of either the first set of die contacts 210 or the second set of die contacts 220 for receiving input signals.

Further, the first and second output enable multiplexers 266a, 266b and the output enable inputs of or associated with the first and second sets of die contacts 210, 220 could be omitted. As the first and second sets of die contacts 210, 220 are coupled to the die contact output (or set of die contact outputs) 278 of the routing core circuitry 270, in such an arrangement the output signal from the downstream circuitry 290 would be supplied to both the first set of die contacts 210 and the second set of die contacts 220.

However, such an arrangement could give rise to unpredictable behaviour of the IC die 200 in use, as the set of die contacts that is not coupled to the external contacts of the IC package in which the IC die 200 is encapsulated would be left floating, which increases the load on the downstream circuitry 290 and could thus lead to unexpected or unpredictable behaviour of the IC die 200. To mitigate this, the first and second sets of die contacts 210, 220 may be provided with integrated pull-down resistors to tie any floating die contacts to a known voltage level.

Further, the provision of the input multiplexer 262 and/or the first and second input enable multiplexers 264a, 264b and/or the first and second output enable multiplexers 266a, 266b may help to reduce the likelihood of timing errors in use of the IC die 200. Although not shown in FIG. 2 for clarity, each of the signal paths between the first and second sets of die contacts 210, 220 and the downstream circuitry 290 will typically include one or more buffers. Each of these buffers introduces some delay or latency into its signal path, and the delay or latency may differ from buffer to buffer, such that each signal path is associated with a different and potentially unknown delay or latency. The provision of the input multiplexer 262 and/or the first and second input enable multiplexers 264a, 264b and/or the first and second output enable multiplexers 266a, 266b permits a known delay or latency to be introduced into each signal path, which can be compensated for by the downstream circuitry 290, thus reducing the likelihood of timing errors.

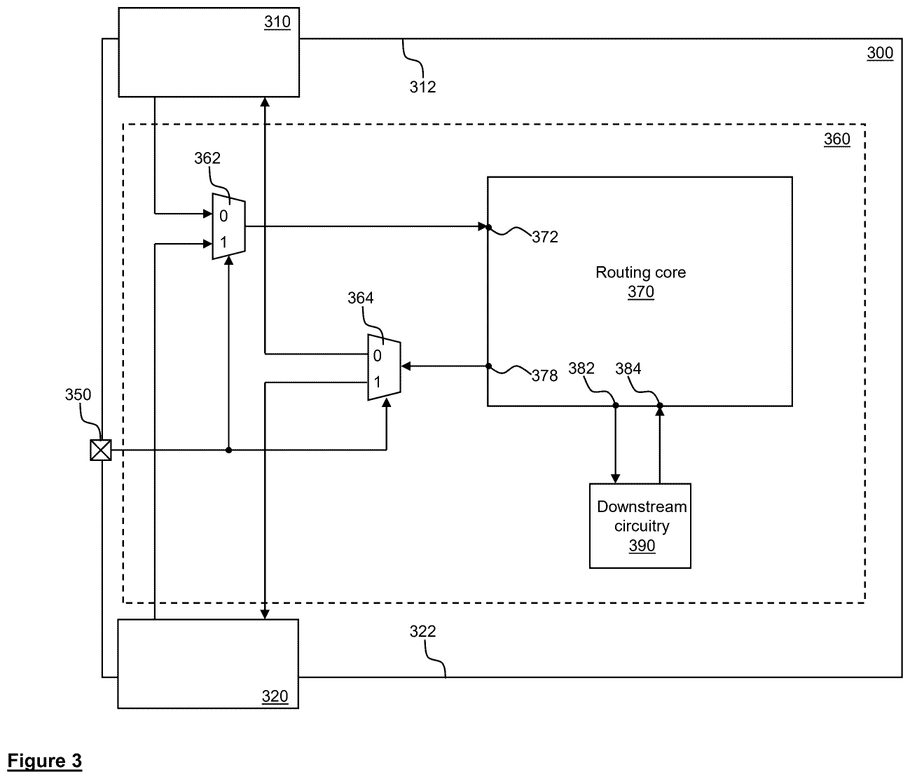

FIG. 3 is schematic representation of a further example IC die according to the present disclosure.

The IC die, shown generally at 300 in FIG. 3, comprises a first set of die contacts 310 and a second set of die contacts 320, which in the illustrated example are disposed, respectively, in first and second regions of the IC die 300. In the illustrated example the first and second sets of die contacts 310, 320 are positioned, respectively, on opposite first and second sides 312, 322 of the IC die 300, but it will be appreciated by those of ordinary skill in the art that the first set of die contacts 310 may be positioned in any region of the IC die 300 that facilitates coupling of the first set of die contacts 310 to external contacts (e.g. pins, pads or balls) of an IC package of a first type or configuration in which the IC die 300 may be encapsulated, and the second set of die contacts 320 may be positioned in any region of the IC die 300 that facilitates coupling of the second set of die contacts 320 to external contacts (e.g. pins, pads or balls) of an IC package of a second type or configuration in which the IC die 300 may be encapsulated.

The first and second sets of die contacts 310, 320 may each include one or more input contacts for receiving input signals to the die 300 and one or more output contacts for outputting signals from the die 300. The IC die 300 further includes a first and second power supply input contacts (which are not shown in FIG. 3 for the sake of clarity) for receiving a positive power supply voltage and a reference power supply voltage (e.g. a ground or negative supply voltage) respectively, to power the IC die 300.

The IC die 300 further includes a package type contact 350, for receiving a package type signal indicative of the type or configuration of a package in which the IC die 300 is encapsulated.

The IC die 300 further includes signal routing circuitry 360 (shown in dashed outline in FIG. 3), which in this example is implemented in digital circuitry, configured to route input signals received at either the first or second set of die contacts 310, 320 to downstream circuitry 390 of the IC die 300, based on the package type signal received at the package type contact 350, and to route output signals from the downstream circuitry 390 to either the first or second set of die contacts 310, 320, again based on the package type signal received at the package type contact 350.

The signal routing circuitry 360 in this example comprises an input multiplexer 362, an output demultiplexer 364, and routing core circuitry 370.

The input multiplexer 362 has a first input (or set of inputs) coupled to the first set of die contacts 310, for receiving one or more input signals from the first set of die contacts 310, a second input (or set of inputs) coupled to the second set of die contacts 320, for receiving one or more input signals from the second set of die contacts 320, and a select input coupled to the package type contact 350, for receiving the package type signal. An output (or set of outputs) of the input multiplexer 362 is coupled to a die contact input (or set of die contact inputs) 372 of the routing core circuitry 370.

The output demultiplexer 364 has an input (or a set of inputs) coupled to a die contact output (or a set of die contact outputs) of the routing core circuitry 370, a first output (or set of outputs) coupled to the first set of die contacts 310, a second output (or set of outputs) coupled to the second set of die contacts 320, and a select input coupled to the package type contact 350, for receiving the package type signal.

The die contact input (or set of die contact inputs) 372 of the routing core circuitry 370 is for supplying input signals received at either the first set of die contacts 310 or the second set of die contacts 320, depending on the type or configuration of the package in which the IC die 200 is encapsulated, to downstream circuitry 390. Similarly, the die contact output (or set of die contact outputs) 378 of the routing core circuitry 370 is for supplying output signals from the downstream circuitry 390 to either the first set of die contacts 310 or the second set of die contacts 320, depending on the type or configuration of the package in which the die 300 is encapsulated.

To these ends, the die contact input (or set of die contact inputs) 372 of the routing core circuitry 370 is coupled, internally of the routing core circuitry 370, to a routing core output (or a set of routing core outputs) 382 to which an input (or set of inputs) of the downstream circuitry 390 is coupled. Similarly, the die contact output (or set of die contact outputs) 378 of the routing core circuitry 370 is coupled, internally of the routing core circuitry 370, to a routing core input (or a set of routing core inputs) 384 to which an output (or set of outputs) of the downstream circuitry 390 is coupled.

The signal routing circuitry 360 is configured to selectively route input signals from the first set of die contacts 310 or the second set of contacts 320 to the downstream circuitry 390, based on the package type signal, and to selectively route output signals from the downstream circuitry 390 to the first set of die contacts 310 or the second set of contacts 320, based on the package type signal, as will now be explained.

If the package type signal is indicative that the IC die 300 is encapsulated in a package of a first configuration, the signal routing circuitry 360 may be operative to route input signals received at the first set of die contacts 310 to the downstream circuitry 390, and may be operative to route output signals received from the downstream circuitry 390 to the first set of die contacts 310. On the other hand, if the package type signal is indicative that the IC die 300 is encapsulated in a package of a second configuration, the signal routing circuitry 360 may be operative to route input signals received at the second set of die contacts 320 to the downstream circuitry 390, and may be operative to route output signals received from the downstream circuitry 390 to the second set of die contacts 320.

The package type signal received at the package type contact 350 is defined during manufacture of the packaged IC containing the IC die 300. For example, if the package is of a first configuration, the first set of die contacts 310 may be coupled to external contacts (e.g. pins, pads, balls or the like) of the package and used for receiving input signals to the IC die 300 and for outputting output signals from the IC die 300. To indicate this, the package type contact 350 may be connected, internally of the IC die 300, to the second power supply input contact, so as to receive the reference power supply voltage. In this case, the select inputs of the input multiplexer 362 and the output demultiplexer 364 each receive a logic 0 signal.

In response to receiving a logic 0 signal at its select input, the input multiplexer 362 couples its first input (or set of inputs) to its output (or set of outputs), such that the first set of die contacts 310 is coupled to the die contact input (or set of die contact inputs) 372 of the routing core circuitry 370, thus selecting the first set of die contacts 310. As noted above, the die contact input (or set of die contact inputs) 372 of the routing core circuitry 370 is internally coupled to the routing core output (or set of outputs) 382. Thus, the first set of die contacts 310 can be coupled to the routing core output (or set of outputs) 382 and thus to the input (or set of inputs) of the downstream circuitry 390.

In response to receiving a logic 0 signal at its select input, the output demultiplexer 364 couples its input (or set of inputs) to its first output (or set of outputs), such that the first set of die contacts 310 is coupled to the die contact output (or set of die contact outputs) 378 of the routing core circuitry 370. As noted above, the die contact output (or set of die contact outputs) 378 of the routing core circuitry 370 is internally coupled to the routing core input (or set of inputs) 384. Thus, the first set of die contacts 310 can be coupled to the routing core input (or set of inputs) 384 and thus to the output (or set of outputs) of the downstream circuitry 390.

In contrast, if the package is of a second configuration, the second set of die contacts 320 may be coupled to the external contacts of the package and used for receiving input signals to the IC die 300 and for outputting output signals from the IC die 300. To indicate this, the package type contact 350 may be connected, internally of the IC die 300, to the first power supply input contact, so as to receive the positive power supply voltage. In this case, the select inputs of the input multiplexer 362, and the output demultiplexer 264 each receive a logic 1 signal.

In response to receiving a logic 1 signal at its select input, the input multiplexer 362 couples its second input (or set of inputs) to its output (or set of outputs), such that the second set of die contacts 320 is coupled to the die contact input (or set of die contact inputs) 372 of the routing core circuitry 370, thus selecting the second set of die contacts 220. As noted above, the die contact input (or set of die contact inputs) 372 of the routing core circuitry 370 is internally coupled to the routing core output (or set of outputs) 382. Thus, the second set of die contacts 320 can be coupled to the routing core output (or set of outputs) 382 and thus to the input (or set of inputs) of the downstream circuitry 390.

In response to receiving a logic 1 signal at its select input, the output demultiplexer 364 couples its input (or set of inputs) to its second output (or set of outputs), such that the second set of die contacts 320 is coupled to the die contact output (or set of die contact outputs) 378 of the routing core circuitry 370. As noted above, the die contact output (or set of die contact outputs) 378 of the routing core circuitry 370 is internally coupled to the routing core input (or set of inputs) 384. Thus, the second set of die contacts 320 can be coupled to the routing core input (or set of inputs) 384 and thus to the output (or set of outputs) of the downstream circuitry 390.

As in the IC die 200 of FIG. 2, in principle the input multiplexer 362 or the output multiplexer 364 could be omitted, such that the first set of die contacts 310 and the second set of die contacts 320 are both coupled to the die contact input (or set of die contact inputs) 372 or to the die contact output (or set of die contact outputs) 378 of the routing core 370. However, the provision of the input multiplexer 362 and the output multiplexer 364 may help to ensure predictable behaviour and reduce the likelihood of timing errors in use of the IC die 300, for the reasons outlined above in relation to the IC die 200 of FIG. 2.

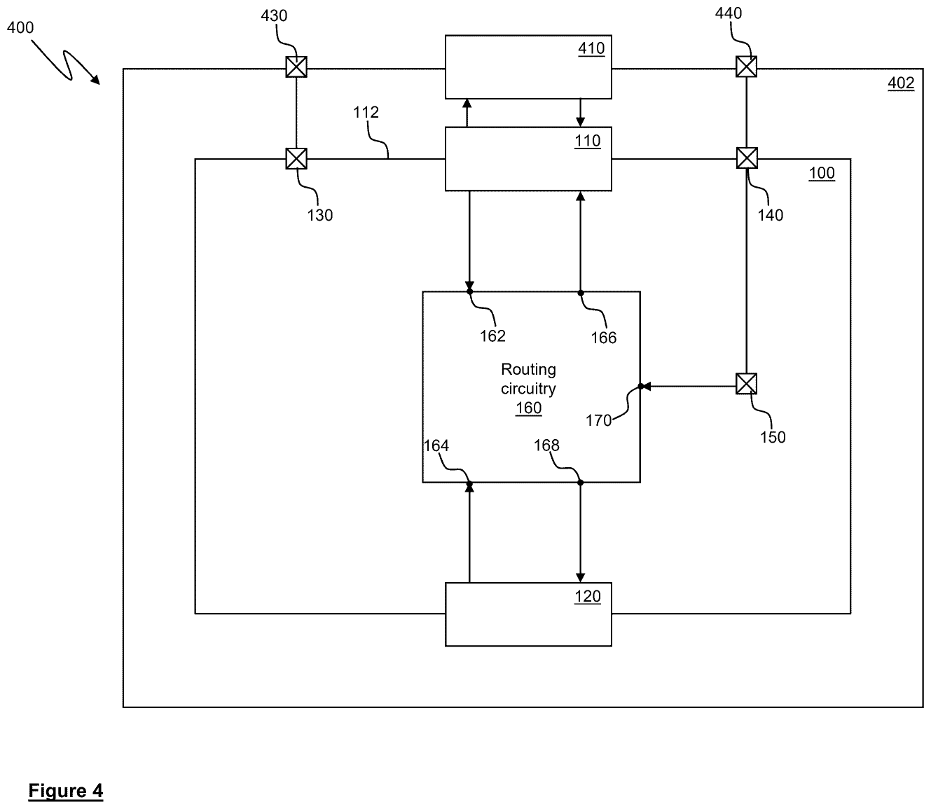

FIG. 4 is a schematic representation of packaged integrated circuit incorporating an IC die according to the present disclosure.

The packaged integrated circuit, shown generally at 400, comprises an IC package 402 having a set of IC package contacts 410 for receiving input signals to, and outputting output signal from, the IC 400. The IC package 402 also has first and second IC power supply input contacts 430, 440 for receiving a positive power supply voltage and a reference power supply voltage, respectively. The IC package contacts 410 and the first and second IC power supply contacts may be, for example, contact balls, pads or pins.

The packaged IC 400 in this example further comprises an IC die 100 of the kind described above with reference to FIG. 1, but it is to be appreciated that the packaged IC 400 could equally comprise an IC die 200 of the kind described above with reference to FIG. 2 or an IC die 300 of the kind described above with reference to FIG. 3.

As shown in FIG. 4, the first and second power supply input contacts 130, 140 of the IC die 100 are coupled, respectively, to the first and second IC power supply input contacts 430, 440 of the IC package 402. The set of IC package contacts 410 in this example is coupled to the first set of die contacts 110 of the IC die 100. The second set of die contacts 120 of the IC die 100 are not coupled to any contacts of the IC package 402.

In the example shown in FIG. 4, the package type contact 150 of the IC die 100 is coupled, internally of the IC die 100 (e.g. by a bond wire or the like), to the second power supply input contact 140 of the IC die 100. Thus, the signal routing circuitry 160 of the IC die 100 receives, as the package type input signal (at its package type input 170), the reference power supply voltage supplied to the IC die 100 via the second IC power supply input contact 440 of the IC package 402 and the second power supply input contact 140 of the IC die 100. This package type input signal is indicative that the first set of die contacts 110 is to be used for receiving input signals and outputting output signals, and accordingly, in use of the packaged IC 400, the signal routing circuitry 160 routes input signals from the first set of die contacts 110 and routes output signals to the first set of die contacts 110.

As will be appreciated by those of ordinary skill in the art, in other example, the IC package 402 may be configured such that the second set of die contacts 120 is coupled to the set of IC package contacts 410. In such examples, the package type contact 150 of the IC die 100 could be coupled, internally of the IC die 100 (e.g. by a bond wire or the like), to the first power supply input contact 130 of the IC die 100, such that the signal routing circuitry 160 receives, at its package type input 170, the positive power supply voltage supplied to the IC die 100 via the first IC power supply input contact 430 of the IC package 402 and the first power supply input contact 130 of the IC die 100. This package type input signal is indicative that the second set of die contacts 120 is to be used for receiving input signals and outputting output signals, and accordingly, in use of the packaged IC 400 in such examples, the signal routing circuitry 160 routes input signals from the second set of die contacts 120 and routes output signals to the second set of die contacts 120.

In the examples discussed above, the package type contact 150 of the IC die 100 is coupled, internally of the IC die 100, to either the first power supply input contact 130 or the second power supply input contact 140 of the IC die 100, such that the signal routing circuitry 160 of the IC die 100 receives, either the positive power supply voltage or the reference supply voltage supplied to the IC die 100 as the package type input signal. In other examples, the package type contact 150 may be coupled, internally of the IC die 100, to some other package type signal source which supplies the package type signal indicative of whether the first set of die contacts 110 or the second set of die contacts is to be used for receiving input signals and outputting output signals.

As noted above, the package type signal received at the package type contact 150 is defined during manufacture of the packaged IC 400 containing the IC die 100. Thus, the internal coupling of the package type contact 150 to the package type signal source (whether the first power supply input contact 130 or the second power supply input contact 140 of the IC die 100, or some other package type signal source internal of the IC die 100) may be effected during manufacture of the IC die 100 (as part of a manufacturing process of the packaged IC 400), based on the type of package in which the IC die 100 is to be encapsulated.

As will be apparent to those of ordinary skill in the art from the foregoing disclosure, the provision of first and second sets of die contacts and signal routing circuitry in the IC dies described above with reference to FIGS. 1 to 3 allows the same IC die to be encapsulated in IC packages of different configurations or types. The first set of die contact pads is positioned to facilitate connection of the die contact pads of the first set to external contacts (e.g. pins, pads, balls or the like) of a package of a first configuration or type, while the second set of die contact pads is positioned to facilitate connection of the die contact pads of the second set to external contacts (e.g. pins, pads, balls or the like) of a package of a second configuration or type. The signal routing circuitry automatically routes input and output signals to and from the IC die to the correct set of die contact pads according to the configuration or type of the package in which the die is encapsulated, as indicated by the signal received at the package type contact.

An IC die of the kind described above with reference to FIGS. 1 to 3 may be used to implement digital, analog or mixed-signal integrated circuitry. Examples of such integrated circuitry include (but are not limited to) digital to analog converter (DAC) circuitry, analog to digital converter (ADC) circuitry, codec circuitry, amplifier circuitry, clock circuitry, power converter (e.g. buck converter, boost converter or buck-boost converter) circuitry, power management circuitry, clock generator circuitry and the like.

The first and second sets of die contacts may be for receiving and/or outputting control and/or data and/or communication signals. In some examples, the first and second sets of die contacts may be for receiving and/or outputting communication signals in accordance with the I²C (inter-integrated circuit) or SPI (serial peripheral interface) communications protocols.

The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages.

Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. An integrated circuit (IC) die configured for packaging in a plurality of different IC packages, the IC die comprising:
a first set of die contacts positioned in a first region of the integrated circuit die;
a second set of die contacts positioned in a second region of the integrated circuit die;
a package type contact; and
routing circuitry configured to selectively route signals to or from either the first set of die contacts or the second set of die contacts based on a package type signal received at the package type contact.

2. The IC die of claim 1, wherein the first set of die contacts are configured to be coupled to external contacts of an integrated circuit package of a first configuration and the second set of die contacts are configured to be coupled to external contacts of an integrated circuit package of a second configuration.

3. The IC die of claim 1, wherein the first set of die contacts is disposed on a first side of the IC die and the second set of die contacts is disposed on a second side of the IC die, wherein the second side is opposed to the first side.

4. The IC die of claim 1, wherein the routing circuitry comprises an input multiplexer configured to select the first set of die contacts or the second set of die contacts for receiving an input signal based on the package type signal.

5. The IC die of claim 1, wherein the routing circuitry comprises:
a first input enable multiplexer configured to selectively enable output contacts of the first set of die contacts based on the package type signal; and
a second input enable multiplexer configured to selectively enable output contacts of the first set of die contacts based on the package type signal.

6. The IC die of claim 4, wherein the routing circuitry further comprises:
a first output enable multiplexer configured to selectively enable output contacts of the first set of die contacts based on the package type signal; and
a second output enable multiplexer configured to selectively enable output contacts of the first set of die contacts based on the package type signal.

7. The IC die of claim 4, wherein the routing circuitry further comprises an output demultiplexer configured to select the first set of die contacts or the second set of die contacts for outputting an output signal based on the package type signal.

8. The IC die of claim 4, wherein the routing circuitry further comprises routing core circuitry configured to couple an output of the input multiplexer to an input of downstream circuitry of the IC die.

9. The IC die of claim 8, wherein the routing core circuitry is further configured to couple an output of the downstream circuitry to the first and second sets of die contacts.

10. The IC die of claim 4, wherein the routing circuitry further comprises routing core circuitry configured to:
couple an output of the input multiplexer to an input of downstream circuitry of the IC die; and
couple an output of the downstream circuitry to an input of the output demultiplexer.

11. The IC die of claim 1, wherein the first and second sets of die contacts are for receiving and/or outputting communications signals.

12. The IC die of claim 11, wherein the communications signals are communication signals according to the Inter-Integrated Circuit (I²C) protocol or the Serial Peripheral Interface (SPI) protocol.

13. An integrated circuit comprising an IC die according to claim 1.

14. A host device comprising an integrated circuit according to claim 13.

15. A host device according to claim 14, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

16. An integrated circuit (IC) comprising an IC die, the IC die comprising:
a first set of die contacts positioned in a first region of the integrated circuit die;
a second set of die contacts positioned in a second region of the integrated circuit die;
a package type contact; and
routing circuitry configured to selectively route signals to or from either the first set of die contacts or the second set of die contacts based on a package type signal received at the package type contact,
wherein the package type contact is coupled, internally of the IC die, to a package type signal source which supplies the package type signal.

17. The IC of claim 16, wherein the package type signal source comprises a first or a second power supply input contact of the IC die.
